(19) United States
(12) Patent Application Publication
(10) Pub. No.: US 2026/0118603 A1
(43) Pub. Date: Apr. 30, 2026

(54) ON-BOARD OPTICAL COUPLING APPARATUS

(71) Applicant: AIP Inc., New Taipei City (TW)

(72) Inventor: Chia LEE, New Taipei City (TW)

(21) Appl. No.: 19/316,144

(22) Filed: Sep. 2, 2025

Related U.S. Application Data
(60) Provisional application No. 63/712,502, filed on Oct. 27, 2024.
(60) Provisional application No. 63/749,839, filed on Jan. 27, 2025.

(51) Int. Cl. G02B 6/42; H01L 25/16

(52) U.S. Cl. CPC G02B 6/4219; G02B 6/4249; H10W 90/00

(57) ABSTRACT

An on-board optical coupling apparatus, used between two data processing devices, includes an optical waveguide including a plurality of alignment path units and waveguide paths. A first photonic device includes a plurality of first return paths and first optical channels. A second photonic device includes a plurality of second return paths and second optical channels. The first optical channels and the second optical channels are optically aligned with respective waveguide paths simultaneously with passive optical alignment of the first return paths, the second return paths, and the alignment path units in a one-time alignment process.

### CROSS REFERENCE TO RELATED APPLICATIONS

This application claims the benefits of U.S. provisional patent application Ser. No. 63/712,502, filed Oct. 27, 2024, and U.S. provisional patent application Ser. No. 63/749,839, filed Jan. 27, 2025, the entire contents of each of which are incorporated herein by reference.

### BACKGROUND OF INVENTION

### 1. Field of Invention

The present invention relates to a technical field of optical couplers, and particularly to an on-board optical coupling apparatus used between two data processing devices.

### 2. Related Art

Optoelectronic integrated circuits (OEICs), using photons instead of electrons for calculation and data transmission in integrated circuits, bring great benefits to the development of industries requiring high-performance data exchange, long-distance interconnection, 5G facilities, and computing equipment. OEICs are configured with photonic integrated circuits (PICs) and electronic integrated circuits (EICs) and are generally co-packaged as co-packaged optics (CPO). Based on OEICs, the use of optical communication can greatly improve the performance of graphical processing units or central processing units. In order to meet the explosive demand for computing speed, the use of multiple processors in a single system has become a development trend. However, there is still no better solution for optical interconnection between multi-processor architectures. Although optical cables may serve as optical couplers for interconnection, they are prone to damage and not conducive to internal space management. In addition, if optical couplers are provided to connect multiple processors, an active alignment process for each optical fiber is generally required to ensure successful optical coupling between them. However, active alignment involves powering on various components within the single system, which makes the process time-consuming and cumbersome.

### SUMMARY OF INVENTION

An object of the present application is to provide an on-board optical coupling apparatus connected between two data processing devices for optical signal transmission without the use of optical fiber cables.

Another object of the present application is to provide an on-board optical coupling apparatus capable of improving manufacturing yield of silicon photonic devices.

Another object of the present application is to provide an on-board optical coupling apparatus capable of being rapidly and actively aligned prior to coupling with target devices.

To achieve the above-mentioned objects, the present application provides an on-board optical coupling apparatus, used between two data processing devices and including an optical waveguide, a first photonic device, and a second photonic device. The optical waveguide includes a first side, a second side, a third side, and a fourth side that collectively define a profile of the optical waveguide, a plurality of alignment path units arranged proximate to at least one of the third side and the fourth side, and a plurality of waveguide paths extending between the first side and the second side. The first photonic device is disposed on one of the data processing devices, proximate to the first side of the optical waveguide, and includes a plurality of first return paths arranged in optical alignment with respective alignment path units of the optical waveguide, and a plurality of first optical channels arranged between the first return paths and in optical alignment with respective waveguide paths. The second photonic device is disposed on the other one of the data processing devices, proximate to the second side of the optical waveguide, and comprising a plurality of second return paths arranged in optical alignment with respective alignment path units of the optical waveguide, and a plurality of second optical channels arranged between the second return paths and in optical alignment with respective waveguide paths. The first optical channels and the second optical channels are optically aligned with respective waveguide paths simultaneously with passive optical alignment of the first return paths, the second return paths, and the alignment path units in a one-time alignment process.

Optionally, one of the plurality of alignment path units comprises two first alignment paths spaced apart from each other, another one of the plurality of alignment path units comprises two second alignment paths spaced apart from each other, and the two first alignment paths and the two second alignment paths are collectively defined as a set of the alignment path units. One of the first alignment paths includes a light input end configured for reception of a first test light signal from an external light transmission member, and the other one of the first alignment paths includes a light output end configured for output of the first test light signal to the external light transmission member. One of the second alignment paths includes a light input end configured for reception of a second test light signal from the external light transmission member, and the other one of the second alignment paths includes a light output end configured for output of the second test light signal to the external light transmission member.

Optionally, each of the first return paths includes a curved segment and two opposite ends optically aligned with corresponding ends of the two first alignment paths on the first side, and each of the second return paths includes a curved segment and two opposite ends optically aligned with corresponding ends of the two second alignment paths on the second side.

Optionally, the light input ends and the light output ends of the set of the alignment path units are positioned on at least one of the third side and the fourth side.

Optionally, the light input ends and the light output ends of the set of the alignment path units are positioned on an upper surface of the optical waveguide.

Optionally, two sets of the alignment path units are symmetrically disposed with respect to each other and located proximate to the third side and the fourth side of the optical waveguide, respectively. The first alignment paths and the second alignment paths in each of the two sets of the alignment path units are symmetrically disposed with respect to each other.

Optionally, the light input end and the light output end of the first alignment paths are positioned away from an end of each of the first alignment paths on the first side, and the light input end and the light output end of the second alignment paths are positioned away from an end of each of the second alignment paths on the second side. The light input ends and the light output ends of each set of the alignment paths are flush with each other.

Optionally, the light input ends and the light output ends of the set of the alignment path units are positioned on the second side of the optical waveguide.

Optionally, at least a corner portion is defined between a side of the second photonic device and the second side of the optical waveguide, and the light input ends and the light output ends are positioned adjoining the corner portion.

Optionally, the light transmission member includes a coupling head, two input optical fibers terminated at the coupling head, and two output optical fibers terminated at the coupling head. The two input optical fibers are in optical communication with the light input ends of the set of the alignment path units, and the two output optical fibers are in optical communication with the light output ends of the set of the alignment path units.

Optionally, the light input ends and the light output ends of the set of the alignment path units are positioned on an upper surface of the optical waveguide, so that the external light transmission member is optically coupled to the set of the alignment path units from a direction above the upper surface of the optical waveguide.

Optionally, the on-board optical coupling apparatus further includes a supporting unit configured to support the optical waveguide, the first photonic device, and the second photonic device.

Optionally, the optical waveguide further includes an optical isolator disposed across the waveguide paths on the optical waveguide.

The present application further provides an on-board optical coupling apparatus, used between two data processing devices and including a first photonic device, a second photonic device, and two light transmission members. The first photonic device includes a plurality of first return paths disposed on a side of the first photonic device, a plurality of second return paths disposed on another side of the first photonic device, and a plurality of first light paths arranged between the first return paths and the second return paths. The second photonic device is disposed adjoining the first photonic device and includes two third alignment paths optically aligned with a respective one of the second return paths, two fourth alignment paths optically aligned with the other one of the second return paths, and a plurality of second light paths arranged in optical alignment with the first light paths. The two light transmission members are optically connected to the first photonic device and the second photonic device, respectively, and each of the light transmission members includes two sets of input optical fibers and output optical fibers disposed adjacent to the input optical fiber. The first light paths and the second light paths are optically aligned with each other simultaneously with passive optical alignment of the first return paths and the two sets of input optical fibers and output optical fibers of one of the light transmission members, and passive optical alignment of the second return paths, the third alignment paths, the fourth alignment paths, and the two sets of input optical fibers and output optical fibers of the other one of the light transmission members in a one-time alignment process.

Optionally, each of the light transmission members includes a coupling head and a plurality of main optical fibers arranged between the two sets of input optical fibers and output optical fibers. The main optical fibers of one of the light transmission members are arranged in optical alignment with the first light paths, and the main optical fibers of the other one of the light transmission members are arranged in optical alignment with the second light paths.

Optionally, each of the first return paths includes a curved segment and two opposite ends optically aligned with corresponding ends of the input optical fiber and the output optical fiber, and each of the second return paths includes a curved segment and two opposite ends optically aligned with corresponding ends of the third alignment paths or the fourth alignment paths.

Optionally, the light transmission members are connected to the two data processing devices respectively to enable optical communication between the data processing devices.

Optionally, the on-board optical coupling apparatus further includes a supporting unit configured to support the first photonic device and the second photonic device.

In the present application, the on-board optical coupling apparatus is connected between the first and the second data processing devices to fulfill optical signal transmission without the use of optical fiber cables, thereby facilitating component arrangement in limited spaces and improving the performance of the entire system as well. In addition, the configurations of the optical waveguide, the first photonic device, the second photonic device are rapidly and passively aligned with one another prior to coupling with the first and the second data processing devices, thereby addressing the issue of time-consuming and cumbersome alignment processes caused by conventional active alignment. Similarly, the configurations of the first photonic device and the second photonic device not only achieve the same functional effect, but also improve manufacturing yield.

### BRIEF DESCRIPTION OF DRAWINGS

To describe the technical solutions in the embodiments of the present application, the following briefly introduces the drawings for describing the embodiments. The drawings in the following description show merely some embodiments of the present application, and a person skilled in the art may still derive other drawings from these drawings without creative efforts.

FIG. 1 is a schematic perspective view of an on-board optical coupling apparatus in accordance with an embodiment of the present application.

FIG. 2 is a top exploded view of FIG. 1.

FIG. 3 is a schematic perspective view of the on-board optical coupling apparatus of FIG. 1 in an optical alignment state with light transmission members.

FIG. 4 is a schematic perspective view of an on-board optical coupling apparatus in accordance with an embodiment of the present application.

FIG. 5 is a schematic perspective view of the on-board optical coupling apparatus of FIG. 4 in an optical alignment state with light transmission members.

FIG. 6 is a schematic perspective view of an on-board optical coupling apparatus in accordance with an embodiment of the present application.

FIG. 7A is a schematic enlarged perspective view of a dashed-circled portion of the on-board optical coupling apparatus of FIG. 6.

FIG. 7B is a schematic perspective view of the on-board optical coupling apparatus of FIG. 6 in an optical alignment state with light transmission members.

FIG. 8 is a schematic perspective view of an optical waveguide in accordance with an embodiment of the present application.

FIG. 9A is a partially enlarged side view of the optical waveguide of FIG. 8.

FIG. 9B is a partially enlarged top plan view of a dashed-circled portion of the optical waveguide of FIG. 8.

FIG. 9C is a schematic structural view illustrating a working principle of an optical isolator in accordance with an embodiment of the present application.

FIG. 10A is a schematic side view of an application of an on-board optical coupling apparatus in accordance with an embodiment of the present application.

FIG. 10B is a schematic side view of an application of an on-board optical coupling apparatus in accordance with an embodiment of the present application.

FIG. 10C is a schematic side view of an application of an on-board optical coupling apparatus in accordance with an embodiment of the present application.

FIG. 11 is a schematic exploded view of an on-board optical coupling apparatus in accordance with an embodiment of the present application.

FIG. 12 is a schematic assembly view of the on-board optical coupling apparatus of FIG. 11.

FIG. 13 is a schematic structural view showing an on-board optical coupling apparatus in a usage state in accordance with an embodiment of the present application.

### DESCRIPTION OF PREFERRED EMBODIMENTS

The following embodiments are referring to the drawings for exemplifying specific implementable embodiments of the present application. Directional terms described by the present application, such as upper, lower, front, back, left, right, inner, outer, side, etc., are only directions by referring to the drawings, and thus the directional terms are used to describe and understand the present application, but the present application is not limited thereto.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present application. In addition, the present application may repeat reference numerals and/or letters in the various examples. This repetition is for the purpose of simplicity and clarity and does not in itself dictate a relationship between the various embodiments and/or configurations discussed.

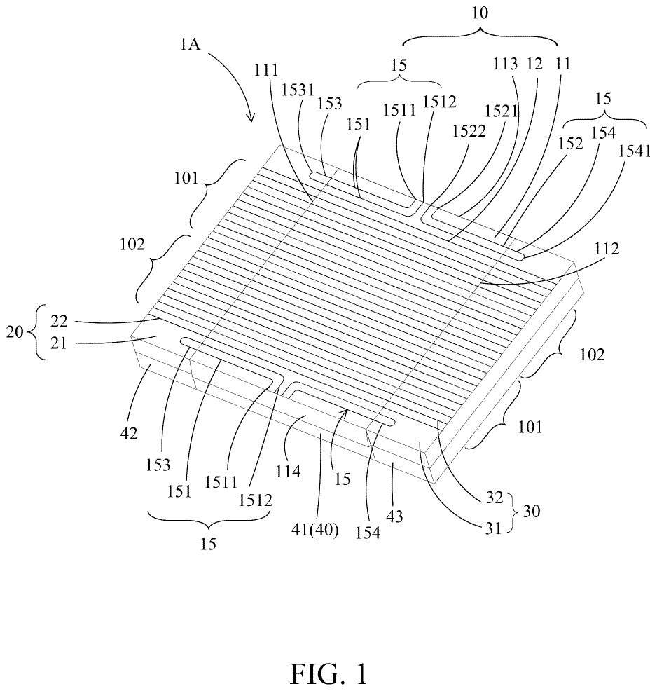

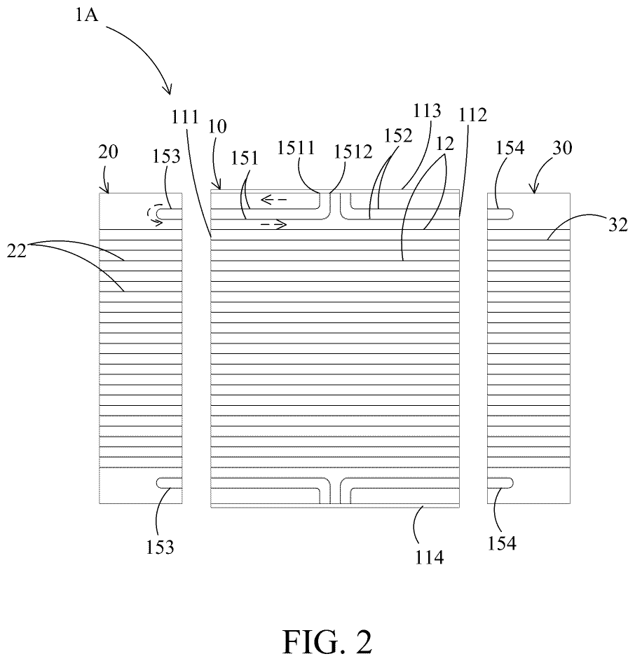

In one aspect, the present application provides an on-board optical coupling apparatus for transmitting data via light signals between two data processing devices, thereby replacing electrical circuits on conventional circuit boards. In some embodiments, the data processing devices may be graphics processing units, central processing units, neural network processing units, etc. Referring to FIGS. 1 and 2, FIG. 1 is a schematic perspective view of an on-board optical coupling apparatus 1A in accordance with an embodiment of the present application, and FIG. 2 is a top exploded view of FIG. 1. The present application provides an on-board optical coupling apparatus 1A including an optical waveguide 10, a first photonic device 20, and a second photonic device 30. Preferably, the first photonic device 20 and the second photonic device 30 are each implemented as a silicon photonic integrated circuit.

In this embodiment, a main load board 41 is provided to support the optical waveguide 10, a first load board 42 is provided to support the first photonic device 20, and a second load board 43 is provided to support the second photonic device 30. The main load board 41, the first load board 42, and the second load board 43 are jointly defined as a supporting unit 40. Alternately, an entire supporting unit 40 is configured to be sized to support the optical waveguide 10, the first photonic device 20, and the second photonic device 30, or only the optical waveguide 10. It should be noted that the main load board 41, the first load board 42, the second load board 43, and the supporting unit 40 may not be shown in other figure drawings for clarity.

As shown in FIG. 1, the optical waveguide 10 includes a first side 111, a second side 112, a third side 113, and a fourth side 114 that collectively define a profile of the optical waveguide 10 and is disposed between the first photonic device 20 and the second photonic device 30. In some embodiments, the first side 111 and the second side 112 are arranged opposite to each other, and the third side 113 and the fourth side 114 are connected between the first side 111 and the second side 112 as top and bottom sides, respectively. In other embodiments, the first side 111, the second side 112, the third side 113, and the fourth side 114 are connected to one another in sequence to define a rectangular profile. The optical waveguide 10 includes a waveguide substrate 11, a plurality of waveguide paths 12, and a plurality of alignment path unit 15. Specifically, the waveguide paths 12 extend between the first side 111 and the second side 112 and positioned between the alignment path units 15. In some embodiments, the waveguide substrate 11 may be made of silica, silicon, or silicon nitride. The waveguide paths 12 are configured to form a planar lightwave circuit (PLC), which may be implemented in various configurations, including, but not limited to, a straight line circuit, a splitter circuit, an arrayed waveguide grating wavelength multiplexer, and a cross connect-type circuit. Preferably, the waveguide substrate 11 is made of silica.

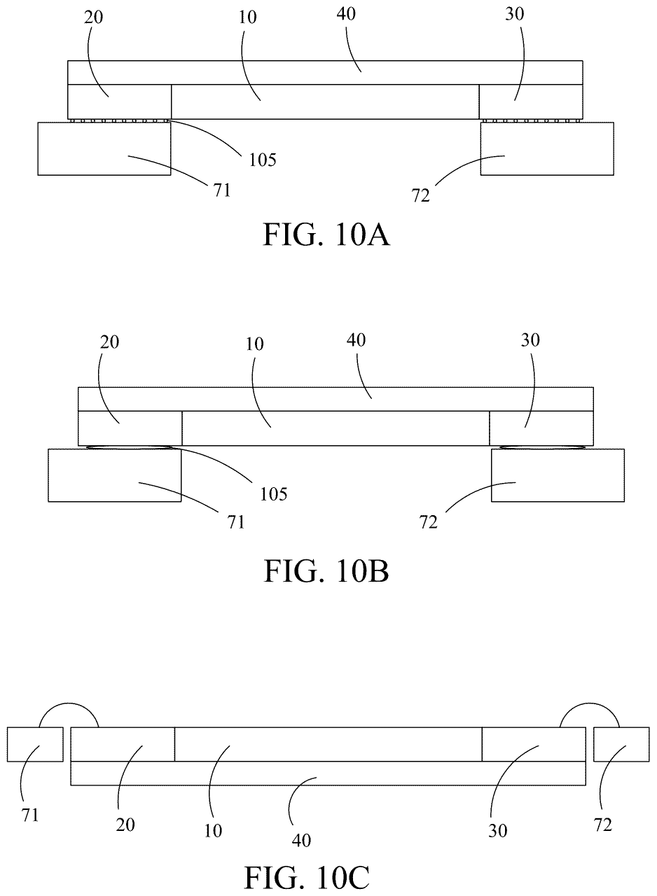

As shown in FIG. 1, the first photonic device 20 includes a first coupling portion 21 and a plurality of first optical channels 22. The first optical channels 22 are arranged to correspond to the waveguide paths 12 of the optical waveguide 10. The second photonic device 30 includes a second coupling portion 31 and a plurality of second optical channels 32. The second optical channels 32 are arranged to correspond to the waveguide paths 12. In some embodiments, the first coupling portion 21 and the second coupling portion 31 are made of silicon. It should be noted that the first and the second optical channels 22 and 32 may be illustrated with shortened lines for clarity in other figure drawings. Specifically, the first photonic device 20 and the second photonic device 30 are disposed on a first data processing device 71 and a second data processing device 72, respectively (as shown in FIG. 10A to 10B, which will be described later). The first photonic device 20 and the second photonic device 30 may be parts of optoelectronic integrated circuits in the first data processing device 71 and the second data processing device 72.

In this embodiment, the first optical channels 22 and the second optical channels 32 each are functionally classified as a light input area 101 and a light output area 102. In some embodiments, light emitters, such as laser diodes (not shown), and light receptors (not shown), such as photodiodes, may be disposed on the data processing devices or on the first photonic device 20 and the second photonic device 30. Preferably, the first photonic device 20 and the second photonic device 30 may be configured to receive light from external light sources equipped with light emitters to provide the required light for optical signal transmission, thereby eliminating the need for integrating light emitters.

In some embodiments, a light signal route is created for the light emitted by the light emitters and to allow the light to travel from the light input area 101 on the side of the first photonic device 20 to pass the waveguide paths 12 of the optical waveguide 10 in a forward direction and then reach the light receptors in the light output area 102 on the side of second photonic device 30. Likewise, another light signal route starts from the light input area 101 on the side of the second photonic device 30 to pass the waveguide paths 12 in a direction opposite to the forward direction to reach the light output area 102 on the side of the first photonic device 20. That is, the two light input areas 101 and the two light output areas 102 on opposite sides of the optical waveguide 10 form a joint signal path.

Referring to FIGS. 1 and 2, two alignment path units 15 are arranged proximate to the third side 113, and two alignment path units 15 are arranged close to the fourth side 114. Each of the alignment path units 15 is configured to enable rapid overall passive alignment, thereby simplifying and easing conventional active alignment methods, such as one-by-one installation alignment, used for the first optical channels 22, the waveguide paths 12, and the second optical channels 32. One of the alignment path units 15 arranged proximate to the third side 113 includes two first alignment paths 151 spaced apart from each other, and the other one of the alignment path units 15 arranged proximate to the third side 113 includes two second alignment paths 152 spaced apart from each other. Preferably, two first alignment paths 151 and two second alignment paths 152 are collectively defined as a set of the alignment path units 15. In detail, two sets of the alignment path units 15 are symmetrically disposed with respect to each other and located proximate to the third side 113 and the fourth side 114 of the optical waveguide 10, respectively. In some embodiments, the first alignment paths 151 and the second alignment paths 152 in each of the two sets of the alignment path units 15 are symmetrically disposed with respect to each other.

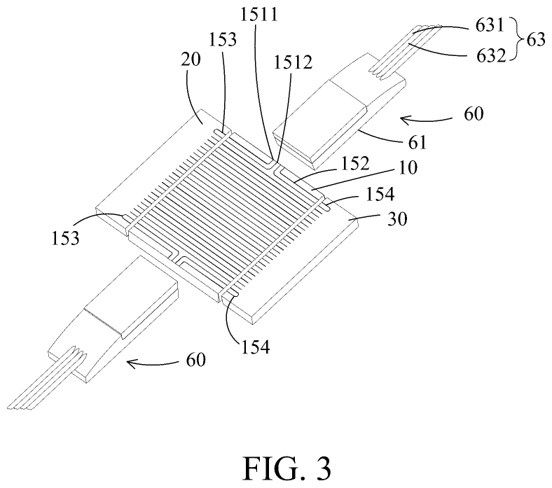

As shown in FIGS. 1 and 2, one end of each of the first alignment paths 151 extends to the first side 111 of the optical waveguide 10, and each of the first alignment paths 151 bends and extends to the third side 113 to form a light input end 1511 and a light output end 1512. The light input end 1511 and the light output end 1512 of the first alignment paths 151 are positioned away from the ends of the first alignment paths 151 on the first side 111. Specifically, the light input end 1511 is configured for reception of a first test light signal from an external light transmission member 60 (as shown in FIG. 3, which will be described later), and the light output end 1512 is configured for output of the first test light signal to the external light transmission member 60.

Similarly, one of the second alignment paths 152 includes a light input end 1521 configured for reception of a second test light signal from the external light transmission member 60, the other one of second alignment paths 152 includes a light output end 1522 configured for output of the second test light signal to the external light transmission member 60. The light input end 1521 and the light output end 1522 of the second alignment paths 152 are positioned away from the ends of the second alignment paths 152 on the second side 112. In this embodiment, the light input ends 1511 and 1521 and the light output ends 1512 and 1522 of the set of the alignment path units 15 are positioned on the third side 113 and the fourth side 114 and function to edge-emitting couple with the light transmission members 60, respectively.

Still referring to FIGS. 1 and 2, two first return path 153 are disposed on the first photonic device 20 and located close to the optical waveguide 10. Each of the first return path 153 has a generally reversed U-shaped configuration such that a curved segment 1531 is formed to make opposite ends of the first return path 153 being located in optical alignment with corresponding ends of the first alignment paths 151 on the first side 111 facing the first photonic device 20. Likewise, two second return path 154 are disposed on the second photonic device 30 and located close to the optical waveguide 10. Each of the second return paths 154 has a generally reversed U-shaped configuration such that a curved segment 1541 is formed to make opposite ends of the second return path 154 being located in optical alignment with corresponding ends of the first alignment paths 152 on the second side 112 facing the first photonic device 20.

Referring to FIG. 3 in combination with FIG. 2, FIG. 3 is a schematic perspective view of the on-board optical coupling apparatus of FIG. 1 in an optical alignment state with the light transmission members 60. As shown in FIG. 3, two light transmission member 60 are provided to optically connect to the first alignment paths 151 and the second alignment paths 152 on the second side 112 and the fourth side 114. Specifically, each of the light transmission members 60 includes a coupling head 61 and an optical cable 63. Specifically, the optical cable 63 includes at least two sets of optical fibers each including an input optical fiber 631 and an output optical fiber 632. The two input optical fibers 631 are terminated at the coupling head 61, and the two output optical fibers 632 are terminated at the coupling head 61. The input optical fiber 631 serves to provide test light signals from an external light intensity adjustable light source (not shown), and the output optical fiber 632 is optically connected to an external optical power meter (not shown). In use, the two input optical fibers 631 are in optical communication with the light input ends 1511 and 1521 of a set of the alignment path units 15, and the two output optical fibers 632 are in optical communication with the light output ends 1512 and 1522 of corresponding set of the alignment path units 15.

As shown in FIG. 2, the first test light signal is input from the light input end 1511 and travels along the first alignment path 151 to the first return path 153 and turns at the curved segment 1531, then is output from the light output end 1512 to the external optical power meter. Similarly, the second test light signal is input from the light input end 1521 and travels along the second alignment path 152 to the second return path 154 and turns at the curved segment 1541, then is output from the light output end 1522 to an external optical power meter. When the light loss of the first and second test signals are below a predetermined value according to the detection of the external optical power meter, the first photonic device 20 and the second photonic device 30 are precisely positioned in place to optically couple with the optical waveguide 10, thereby concurrently achieving optical alignment of each set of the first optical channels 22, the second optical channel 32, and the waveguide paths 12 among the first optical channels 22, the waveguide paths 12, and the second optical channel 32, without the process of individually optically aligning each of the first optical channels 22 and the second optical channels 32 with the waveguide paths 12.

In detail, the first optical channels 22, the second optical channel 32, and the waveguide paths 12 are produced by a same set of optical mask through epitaxy and lithographic processes. If one or two sets of the first optical channels 22, the second optical channels 32, and the waveguide paths 12 are aligned, then all sets of the first optical channels 22, the second optical channels 32, and the waveguide paths 12 are aligned. With the above structure, the first optical channels 22 and the second optical channels 32 are optically aligned with all waveguide paths 12 simultaneously with passive optical alignment of few sets of the first return paths 153, the second return paths 154, and the alignment path units 15 in a one-time alignment process. It is noted that the passive optical alignment refers to an optical alignment in which the optical sources of the first photonic device 20 and the second photonic device 30 are not powered during assembly, thereby reducing alignment time and enhancing optical coupling efficiency.

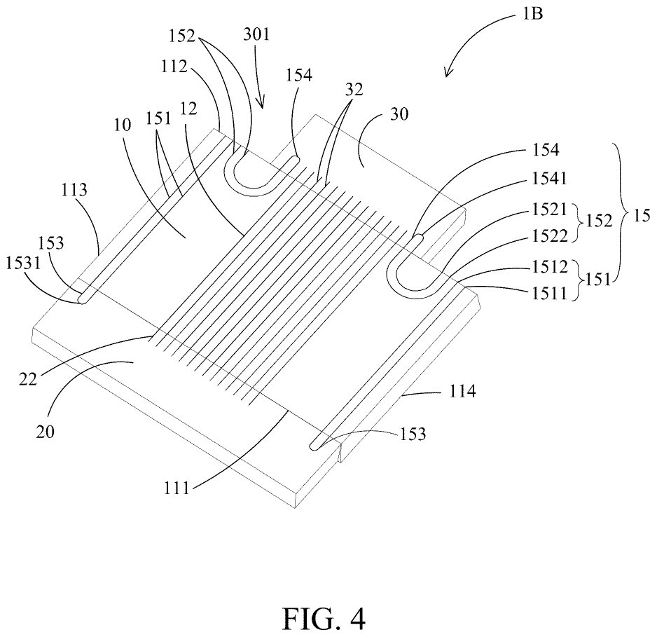

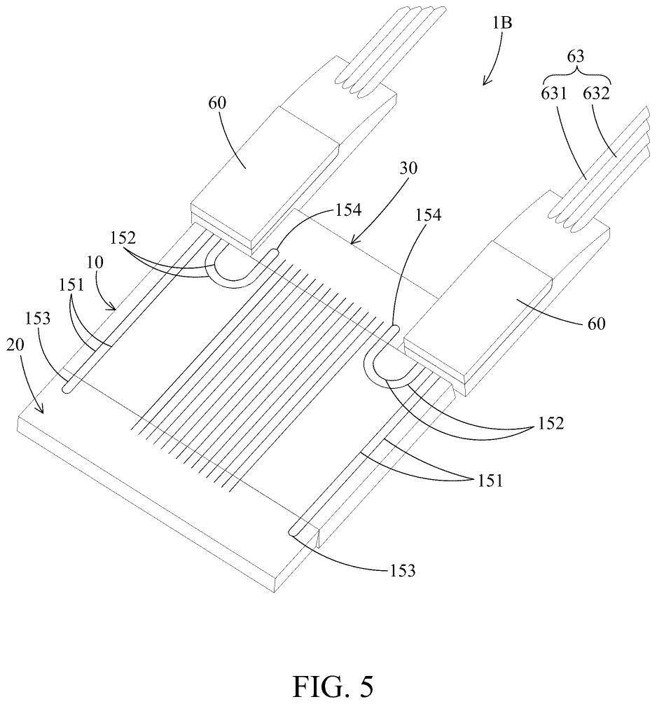

Referring to FIGS. 4 and 5, FIG. 4 illustrates an on-board optical coupling apparatus 1B according to another embodiment of the present application, and FIG. 5 is a schematic perspective view of the on-board optical coupling apparatus 1B of FIG. 4 in an optical alignment state with the light transmission members 60. The on-board optical coupling apparatus 1B mainly differs from the on-board optical coupling apparatus 1A in that the first photonic device 20 is larger than the second photonic device 30 such that a corner portion 301 is formed between the second side 112 of the optical waveguide 10 and a side of the second photonic device 30. The arrangement of the first alignment path 151 and the second alignment path 152 are different from those of the on-board optical coupling apparatus 1A.

As shown in FIGS. 4 and 5, the light input end 1511 and the light output end 1512 of the first alignment paths 151 start from the second side 112 of the optical waveguide 10, the light input end 1521 and the light output end 1522 of the second alignment paths 152 also start from the second side 112, and the second alignment paths 152 are in optical alignment with the second return path 154 on the second side 112 of the optical waveguide 10. That is, the light input ends 1511 and 1521 and the light output ends 1512 and 1522 are positioned on the second side 112 of the optical waveguide 10 and adjoin the corner portion 301. Two light transmission member 60 are optically connected to the light input ends 1511 and 1521 and the light output ends 1512 and 1522 at both corner portions 301, respectively.

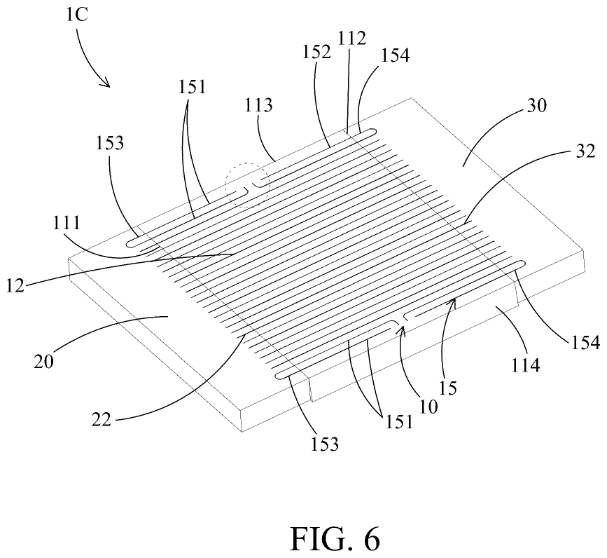

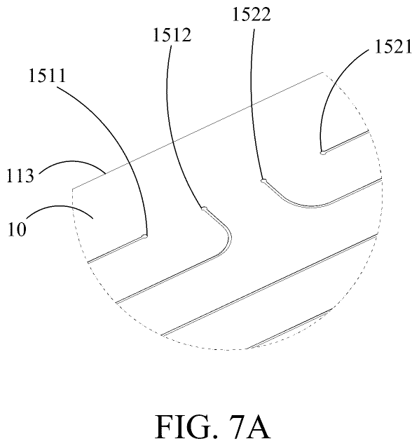

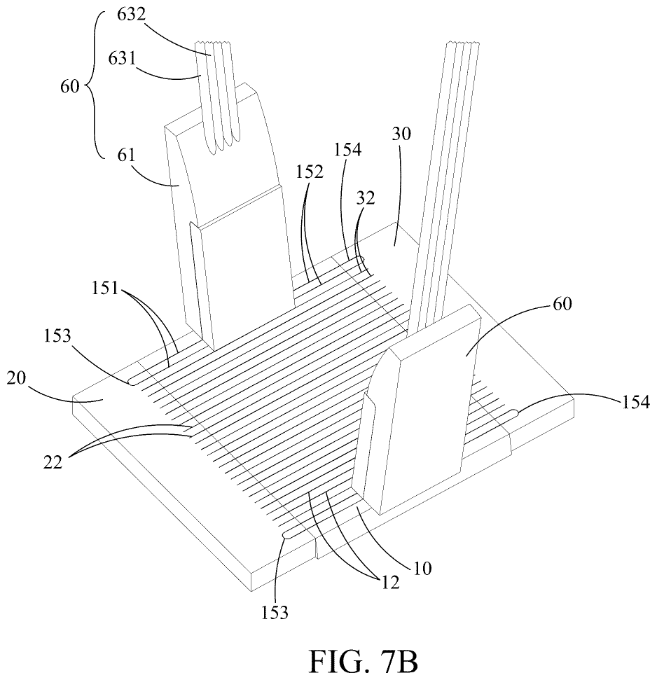

Referring to FIGS. 6, 7A, and 7B, FIG. 6 is a schematic perspective view of an on-board optical coupling apparatus 1C according to another embodiment of the present application, FIG. 7A is a schematic enlarged perspective view of a dashed-circled portion of the on-board optical coupling apparatus 1C of FIG. 6, FIG. 7B is a schematic perspective view of the on-board optical coupling apparatus 1C of FIG. 6 in an optical alignment state with the light transmission members 60. The on-board optical coupling apparatus 1C, which is mainly different from the on-board optical coupling apparatus 1A in that the light transmission member 60 is optically coupled to the first alignment paths 151 and the second alignment paths 152 from a direction above an upper surface of the optical waveguide 10.

As shown in FIGS. 6 and 7A, the light input ends 1511 and 1521 and the light output ends 1512 and 1522 of the set of the alignment path units 15 adjacent to the third side 113 are positioned on the upper surface of the optical waveguide 10. Specifically, as shown in FIGS. 7A and 7B, the light input ends 1511 and 1521 and the light output ends 1512 and 1522 of the set of the alignment path units 15 are flush with each other. In this embodiment, the light input ends 1511 and 1521 and the light output ends 1512 and 1522 are surface-coupled with the light transmission members 60, and, unlike those shown in FIG. 1, are not positioned on the third side 113. In this embodiment, the first test light signal is input from top to bottom to the optical waveguide 10 and returns from bottom to top to the light transmission member 60, which facilitates component arrangement in limited spaces, particularly when the peripheral space around of the optical waveguide 10 is insufficient for placing the light transmission members 60. Likewise, the light input ends 1511 and 1521 and the light output ends 1512 and 1522 of the set of the alignment path units 15 symmetrically positioned adjacent to the fourth side 114 are surface-coupled with the other light transmission members 60.

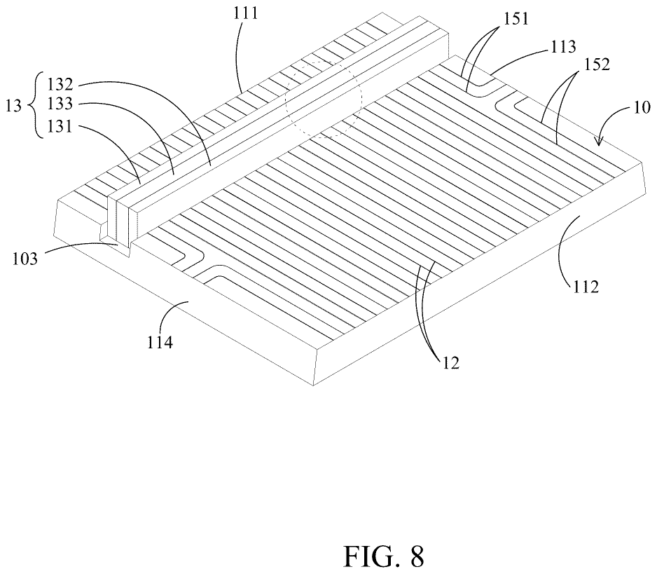

Referring to FIG. 8, illustrating a schematic perspective view of the optical waveguide 10 in accordance with an embodiment of the present application, a slot 103 is formed in the optical waveguide 10 and extends across the waveguide paths 12, and an optical isolator 13 is inserted in the slot 103 across the waveguide paths 12 on the optical waveguide 10. The optical isolator 13 includes an input polarization element 131, an output polarization element 132, and an optical rotator 133 disposed between the input polarization element 131 and the output polarization element 132. The optical isolator 13 is configured to enable the light from the waveguide paths 12 to propagate in a desired direction to the first photonic device 20 and the second photonic device 30 and reduce interference caused by reflected light, thereby exhibiting a relatively low propagation loss in the desired direction.

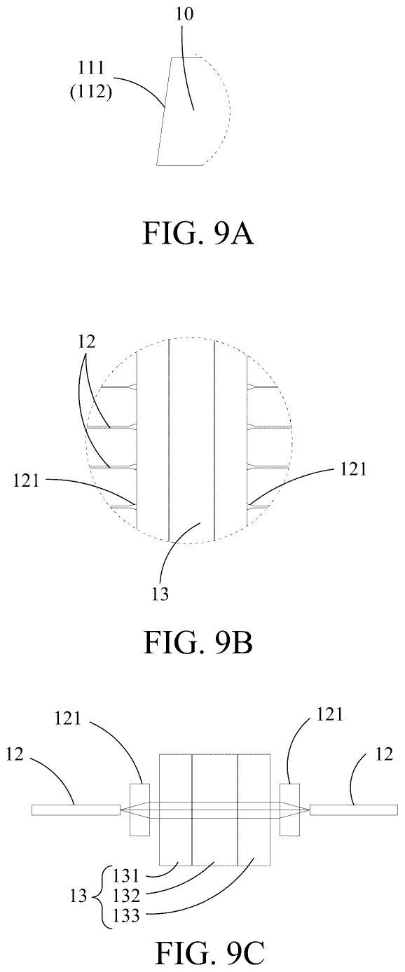

Referring to FIG. 9A to 9C, FIG. 9A is a partially enlarged side view of the optical waveguide 10 of FIG. 8, and FIG. 9B is a partially enlarged top plan view of the optical waveguide 10 of FIG. 8, and FIG. 9C is a schematic structural view illustrating a working principle of an optical isolator 13 according to an embodiment of the present application. Specifically, the optical waveguide 10 further includes a plurality of light directing structures 121 located at opposite side portions of the slot 103. In detail, each set of the light directing structures 121 expands from the waveguide path 12 in such a way that the light directing structures 121 form an aperture greater than a diameter of the waveguide path 12. As shown in FIG. 9C, in the event that the light is reflected when travelling between the first optical channels 22 and the second optical channels 32, it will be reflected back by the light directing structure 121 and go in the desired direction to the waveguide paths 12.

Referring to FIGS. 10A and 10B, the on-board optical coupling apparatus 1A/1B/1C is electrically mounted on the first and the second data processing devices 71 and 72 through flip-chip bonding technologies by using a plurality of electrically conductive pillars or balls 105. Referring to FIG. 10C, the on-board optical coupling apparatus 1A/1B/1C is connected to the first and the second data processing devices 71 and 72 through wire bonding.

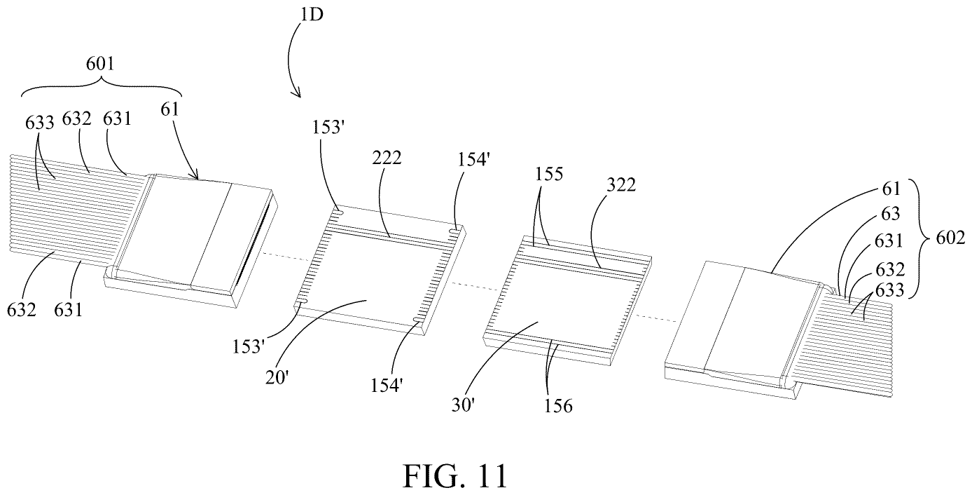

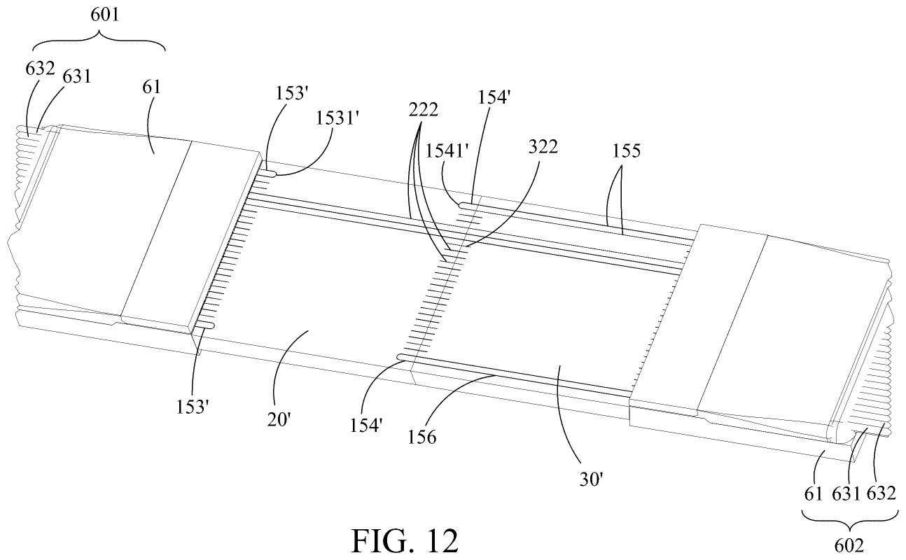

Referring to FIGS. 11 and 12, FIG. 11 illustrates a schematic exploded view of an on-board optical coupling apparatus 1D according to another embodiment of the present application, and FIG. 12 is a schematic assembly view of the on-board optical coupling apparatus 1D of FIG. 11. In this embodiment, the on-board optical coupling device 1D is provided without the optical waveguide 10. Specifically, the on-board optical coupling apparatus 1D includes a first photonic device 20′, a second photonic device 30′ disposed adjoining the first photonic device 20′, and two light transmission members 601 and 602 optically connected to the first photonic device 20′ and the second photonic device 30′, respectively. Preferably, the first photonic device 20′ and the second photonic device 30′ are each implemented as a silicon photonic integrated circuit. In comparison with the first and second photonic devices 20 and 30 shown in the above-mentioned embodiments, each of the first photonic device 20′ and the second photonic device 30′ in some embodiments can omit light emitters, such as laser diodes (not shown), and light receptors (not shown), such as photodiodes to reduce in size to improve manufacturing yield.

As shown in FIGS. 11 and 12, the first photonic device 20′ includes a plurality of first return paths 153′ disposed on a side of the first photonic device 20′, a plurality of second return paths 154′ disposed on another side of the first photonic device 20′, and a plurality of first light paths 222 arranged between the first return paths 153′ and the second return paths 154′. The second photonic device 30′ includes two third alignment paths 155 optically aligned with a respective one of the second return paths 154′, two fourth alignment paths 156 optically aligned with the other one of the second return paths 154′, and a plurality of second light paths 322 arranged in optical alignment with the first light paths 222. Each of the light transmission members 601 and 602 includes a coupling head 61 and a plurality of main optical fibers 633 arranged between two sets of input optical fiber 631 and output optical fiber 632. The main optical fibers 633 of one of the light transmission members 601 and 602 are arranged in optical alignment with the first light paths 222, and the main optical fibers 633 of the other one of the light transmission members 601 and 602 are arranged in optical alignment with the second light paths 322.

As shown in FIG. 12, each of the first return paths 153′ includes a curved segment 1531′ and two opposite ends optically aligned with corresponding ends of the input optical fiber 631 and the output optical fiber 632. Each of the second return paths 154′ includes a curved segment 1541′ and two opposite ends optically aligned with corresponding ends of the third alignment paths 155 and the fourth alignment paths 156. The two sets of the third alignment paths 155 are optically connected to the coupling head 61 of the light transmission member 602. It should be noted that the input optical fiber 631 and the output optical fiber 632 shown in FIGS. 11 and 12 may operate in a manner consistent with the embodiments described above. Therefore, their functions will not be reiterated herein. In some embodiments, each of the transmission members 601 and 602 may include a transceiver head (not shown) connected to a mating connector (not shown) for providing and receiving optical signal.

With the above structure, the first light paths 222 and the second light paths 322 are optically aligned with each other simultaneously with passive optical alignment of the first return paths 153′ and the two sets of the input optical fiber 631 and the output optical fiber 632 of one of the light transmission members 601 and 602, and passive optical alignment of the second return paths 154′, the third alignment paths 155, the fourth alignment paths 156, and the two sets of the input optical fiber 631 and the output optical fiber 632 of the other one of the light transmission members 601 and 602 in a one-time alignment process. The light transmission members 601 and 602 are connected to the data processing devices 71 and 72, respectively, to enable optical communication between the data processing devices 71 and 72 through the first and second photonic devices 20′ and 30′.

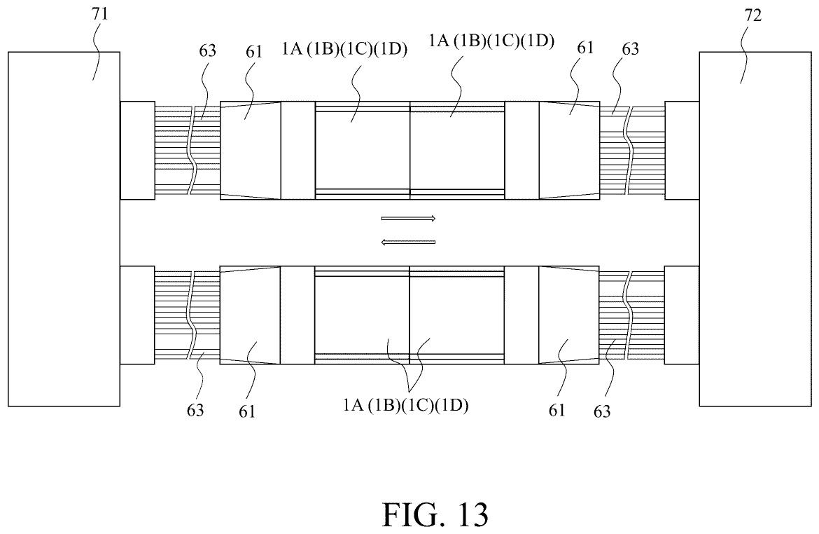

Referring to FIG. 13, FIG. 13 is a schematic structural view showing the on-board optical coupling apparatus in a usage state in accordance with an embodiment of the present application. In some embodiments, the first and the second optical data processing devices 71 and 72 are optical data processing devices. The on-board optical coupling apparatus 1D is optically coupled between a first and a second optical data processing devices 71 and 72 to achieve all optical network. Similarly, the on-board optical coupling apparatus 1D as shown in FIGS. 11 and 12 can be used for all optical network as well. The first and the second optical data processing devices 71 and 72 are all optical processors and the on-board optical coupling apparatus 1D communicates with the first and the second optical data processing devices 71 and 72 through optical signal. In some embodiments, the on-board optical coupling apparatus 1A/1B/1C may be employed in the all optical network structure as shown in FIG. 13.

In the present application, the on-board optical coupling apparatus is connected between the first and the second data processing devices to fulfill optical signal transmission without the use of optical fiber cables, thereby facilitating component arrangement in limited spaces and improving the performance of the entire system as well. In addition, the configurations of the optical waveguide, the first photonic device, the second photonic device are rapidly and passively aligned with one another prior to coupling with the first and the second data processing devices, thereby addressing the issue of time-consuming and cumbersome alignment processes caused by conventional active alignment. Similarly, the configurations of the first photonic device and the second photonic device not only achieve the same functional effect, but also improve manufacturing yield.

While the application has been disclosed in conjunction with a description of certain embodiments, including those that are currently believed to be the preferred embodiments, the detailed description is intended to be illustrative and should not be understood to limit the scope of the present application. As would be understood by one of ordinary skill in the art, embodiments other than those described in detail herein are encompassed by the present application. Modifications and variations of the described embodiments may be made without departing from the scope of the application.

What is claimed is:

1. An on-board optical coupling apparatus, used between two data processing devices, and comprising:
an optical waveguide comprising a first side, a second side, a third side, and a fourth side that collectively define a profile of the optical waveguide, a plurality of alignment path units arranged proximate to at least one of the third side and the fourth side, and a plurality of waveguide paths extending between the first side and the second side;
a first photonic device disposed on one of the data processing devices, proximate to the first side of the optical waveguide, and comprising a plurality of first return paths arranged in optical alignment with respective alignment path units of the optical waveguide, and a plurality of first optical channels arranged between the first return paths and in optical alignment with respective waveguide paths; and
a second photonic device disposed on the other one of the data processing devices, proximate to the second side of the optical waveguide, and comprising a plurality of second return paths arranged in optical alignment with respective alignment path units of the optical waveguide, and a plurality of second optical channels arranged between the second return paths and in optical alignment with respective waveguide paths;
wherein the first optical channels and the second optical channels are optically aligned with respective waveguide paths simultaneously with passive optical alignment of the first return paths, the second return paths, and the alignment path units in a one-time alignment process.

2. The on-board optical coupling apparatus of claim 1, wherein one of the plurality of alignment path units comprises two first alignment paths spaced apart from each other, another one of the plurality of alignment path units comprises two second alignment paths spaced apart from each other, and the two first alignment paths and the two second alignment paths are collectively defined as a set of the alignment path units, wherein one of the first alignment paths comprises a light input end configured for reception of a first test light signal from an external light transmission member, and the other one of the first alignment paths comprises a light output end configured for output of the first test light signal to the external light transmission member, and wherein one of the second alignment paths comprises a light input end configured for reception of a second test light signal from the external light transmission member, and the other one of the second alignment paths comprises a light output end configured for output of the second test light signal to the external light transmission member.

3. The on-board optical coupling apparatus of claim 2, wherein each of the first return paths comprises a curved segment and two opposite ends optically aligned with corresponding ends of the two first alignment paths on the first side, and each of the second return paths comprises a curved segment and two opposite ends optically aligned with corresponding ends of the two second alignment paths on the second side.

4. The on-board optical coupling apparatus of claim 3, wherein the light input ends and the light output ends of the set of the alignment path units are positioned on at least one of the third side and the fourth side.

5. The on-board optical coupling apparatus of claim 3, wherein the light input ends and the light output ends of the set of the alignment path units are positioned on an upper surface of the optical waveguide.

6. The on-board optical coupling apparatus of claim 2, wherein two sets of the alignment path units are symmetrically disposed with respect to each other and located proximate to the third side and the fourth side of the optical waveguide respectively, wherein the first alignment paths and the second alignment paths in each of the two sets of the alignment path units are symmetrically disposed with respect to each other.

7. The on-board optical coupling apparatus of claim 2, wherein the light input end and the light output end of the first alignment paths are positioned away from an end of each of the first alignment paths on the first side, and the light input end and the light output end of the second alignment paths are positioned away from an end of each of the second alignment paths on the second side, wherein the light input ends and the light output ends of each set of the alignment paths are flush with each other.

8. The on-board optical coupling apparatus of claim 2, wherein the light input ends and the light output ends of the set of the alignment path units are positioned on the second side of the optical waveguide.

9. The on-board optical coupling apparatus of claim 8, wherein at least a corner portion is defined between a side of the second photonic device and the second side of the optical waveguide, and the light input ends and the light output ends are positioned adjoining the corner portion.

10. The on-board optical coupling apparatus of claim 2, wherein the light transmission member comprises a coupling head, two input optical fibers terminated at the coupling head, and two output optical fibers terminated at the coupling head, wherein the two input optical fibers are in optical communication with the light input ends of the set of the alignment path units, and the two output optical fibers are in optical communication with the light output ends of the set of the alignment path units.

11. The on-board optical coupling apparatus of claim 10, wherein the light input ends and the light output ends of the set of the alignment path units are positioned on an upper surface of the optical waveguide, so that the external light transmission member is optically coupled to the set of the alignment path units from a direction above the upper surface of the optical waveguide.

12. The on-board optical coupling apparatus of claim 1, further comprising a supporting unit configured to support the optical waveguide, the first photonic device, and the second photonic device.

13. The on-board optical coupling apparatus of claim 1, wherein the optical waveguide further comprises an optical isolator disposed across the waveguide paths on the optical waveguide.

14. An on-board optical coupling apparatus, used between two data processing devices, and comprising:
a first photonic device comprising a plurality of first return paths disposed on a side of the first photonic device, a plurality of second return paths disposed on another side of the first photonic device, and a plurality of first light paths arranged between the first return paths and the second return paths;
a second photonic device disposed adjoining the first photonic device and comprising two third alignment paths optically aligned with a respective one of the second return paths, two fourth alignment paths optically aligned with the other one of the second return paths, and a plurality of second light paths arranged in optical alignment with the first light paths; and
two light transmission members optically connected to the first photonic device and the second photonic device, respectively, and each of the light transmission members comprising two sets of input optical fibers and output optical fibers disposed adjacent to the input optical fiber;
wherein the first light paths and the second light paths are optically aligned with each other simultaneously with passive optical alignment of the first return paths and the two sets of input optical fibers and output optical fibers of one of the light transmission members, and passive optical alignment of the second return paths, the third alignment paths, the fourth alignment paths, and the two sets of input optical fibers and output optical fibers of the other one of the light transmission members in a one-time alignment process.

15. The on-board optical coupling apparatus of claim 14, wherein each of the light transmission members comprises a coupling head and a plurality of main optical fibers arranged between the two sets of input optical fibers and output optical fibers, wherein the main optical fibers of one of the light transmission members are arranged in optical alignment with the first light paths, and the main optical fibers of the other one of the light transmission members are arranged in optical alignment with the second light paths.

16. The on-board optical coupling apparatus of claim 15, wherein each of the first return paths comprises a curved segment and two opposite ends optically aligned with corresponding ends of the input optical fiber and the output optical fiber, and each of the second return paths comprises a curved segment and two opposite ends optically aligned with corresponding ends of the third alignment paths or the fourth alignment paths.

17. The on-board optical coupling apparatus of claim 14, wherein the light transmission members are connected to the two data processing devices respectively to enable optical communication between the data processing devices.

18. The on-board optical coupling apparatus of claim 14, further comprising a supporting unit configured to support the first photonic device and the second photonic device.
